(19) United States
(12) Patent Application Publication
(10) Pub. No.: US 2025/0084205 A1
(43) Pub. Date: Mar. 13, 2025

(54) RESIN COMPOSITION

(71) Applicant: Shin-Etsu Chemical Co., Ltd., Tokyo (JP)

(72) Inventors: Hiroyuki IGUCHI, Annaka-shi (JP); Atsushi TSUURA, Annaka-shi (JP); Yuki KUDO, Annaka-shi (JP); Yoshihiro TSUTSUMI, Annaka-shi (JP)

(73) Assignee: Shin-Etsu Chemical Co., Ltd., Tokyo (JP)

(21) Appl. No.: 18/789,287

(22) Filed: Jul. 30, 2024

(30) Foreign Application Priority Data
Aug. 8, 2023 (JP) 2023-129031

(51) Int. Cl. C08G 59/44; C08G 59/24; C08G 59/68; C08J 5/24; H05K 1/03

(52) U.S. Cl. CPC C08G 59/44; C08G 59/245; C08G 59/686; C08J 5/249; C08J 2363/02; H05K 1/0366

(57) ABSTRACT

Provided is a resin composition containing:
(A) a first cyclic imide compound of the following formula (1):

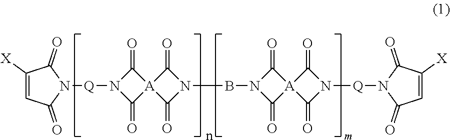

wherein A independently represents a tetravalent organic group having a cyclic structure, Q independently represents an alicyclic hydrocarbon group of the formula (2):

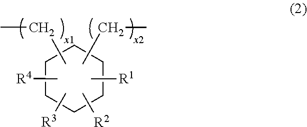

wherein R¹, R², R³, and R⁴ independently represent a hydrogen atom or an alkyl group having 1 to 5 carbon atoms, and x1 and x2 are each 0 to 4,
wherein B independently represents a divalent hydrocarbon group (excluding the group represented by the formula (2)),
wherein X represents a hydrogen atom or a methyl group, and
wherein n is 1 to 200;
(B) a second cyclic imide compound of the formula (3):

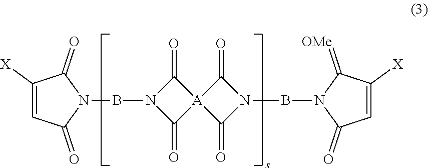

wherein A, B, and X are defined as above in the formula (1), and s is 0 to 200;
(C) an epoxy compound; and
(D) a curing catalyst.

### BACKGROUND OF THE INVENTION

### Field of the Invention

The present invention relates to a resin composition, a prepreg, a copper-clad laminate, and a printed-wiring board.

### Background Art

In recent years, the speed and capacity of signals used in electronic devices such as mobile communication devices as typified by cellular phones, base station devices therefor, network infrastructure devices such as servers and routers, and large computers have been increasing year by year. Accordingly, high-frequency bands such as the 20 GHz region are used for printed-wiring boards mounted on these electronic devices, and the characteristics required of materials for printed-wiring boards, including low relative permittivity, low dielectric tangent, low coefficient of thermal expansion, high heat resistance, and low water absorbency, are becoming higher.

Materials that can potentially meet these characteristics include epoxy resins, modified polyphenylene ether resins, aromatic maleimide resins, and aliphatic maleimide resins (JP-A-2019-1965, JP-A-2018-28044, and JP-A-2020-176190). However, epoxy resins do not have sufficiently low relative permittivity or dielectric tangent, whereas modified polyphenylene ether resins and maleimide resins do not have sufficient adhesion force to low-profile copper; therefore, they do not sufficiently meet the characteristics required of materials for copper-clad laminates and printed-wiring boards. As the frequency band used becomes even higher, lower relative permittivity, lower dielectric tangent, and higher adhesion to low-profile copper will be required.

Aliphatic maleimide resins have low relative permittivity, low dielectric tangent, and exhibits high adhesion force to low-profile copper (JP-A-2020-12026). However, a resin composition containing an aliphatic maleimide resin is disadvantageous in that it has low chemical resistance due to the long-chain alkyl group of the aliphatic maleimide and tends to cause peeling of copper when treated with a desmear solution such as a permanganate solution after the formation of via holes by drilling or laser processing during the production of printed-wiring boards. Although a composition containing an aliphatic maleimide resin with a short alkyl chain has been disclosed, there is no investigation on, for example, desmear treatment resistance or adhesion to low-profile copper (JP-A-2021-181531).

### SUMMARY OF THE INVENTION

Thus, it is an object of the present invention to provide a resin composition that forms a cured product with not only low relative permittivity and low dielectric tangent, but also high adhesion to low-profile copper, high chemical resistance, and high durability.

The inventors of the present invention have diligently conducted studies to solve the above problems and have found that the following resin composition can achieve the above object, thus completing the present invention.

That is, the present invention provides the following resin composition and other products.

A resin composition according to a first aspect of the present invention contains the following components (A) to (D):
(A) a first cyclic imide compound represented by the following formula (1):

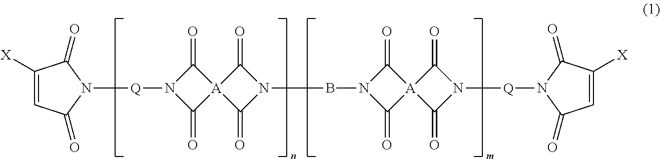

wherein A independently represents a tetravalent organic group having a cyclic structure, Q independently represents an alicyclic hydrocarbon group represented by the following formula (2):

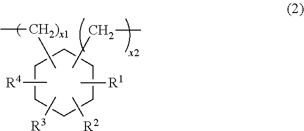

wherein R¹, R², R³, and R⁴ independently represent a hydrogen atom or an alkyl group having 1 to 5 carbon atoms, and x1 and x2 are each 0 to 4,
B independently represents any one of divalent hydrocarbon groups represented by the following formulae:

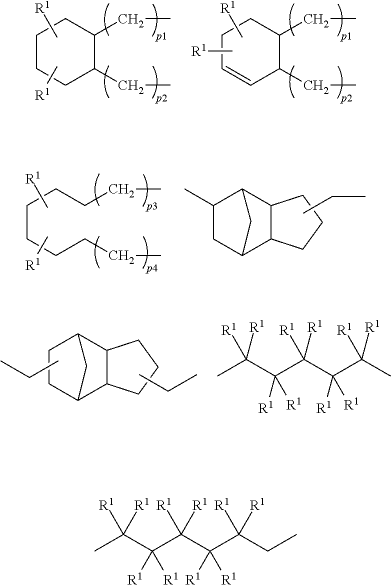

wherein bonds that are yet unbonded to substituent groups are to be bonded to nitrogen atoms forming cyclic imide structures in the formula (1), each R¹ independently represents a hydrogen atom or a linear or branched alkyl group having 1 to 20 carbon atoms, p¹ and p² are each a number of 5 or more and may be identical to or different from each other, and p³ and p⁴ are each a number of 0 or more and may be identical to or different from each other.
X represents a hydrogen atom or a methyl group, n is 1 to 200, m is 0 to 200, provided that when m is 1 or more, n:m=1:1 to 4:1, and repeating units identified by n and m are present in any order;
(B) a second cyclic imide compound represented by the following formula (3):

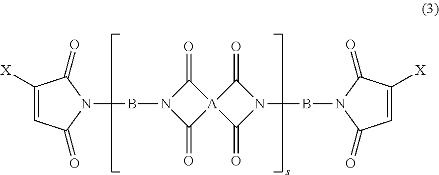

wherein A independently represents a tetravalent organic group having a cyclic structure, B independently represents any one of divalent hydrocarbon groups represented by the following formulae:

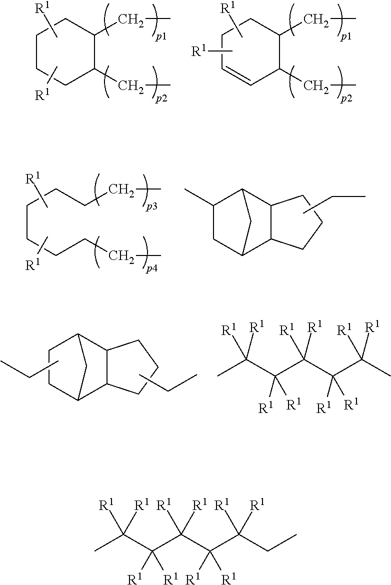

wherein bonds that are yet unbonded to substituent groups are to be bonded to nitrogen atoms forming cyclic imide structures in the formula (3), each R¹ independently represents a hydrogen atom or a linear or branched alkyl group having 1 to 20 carbon atoms, p¹ and p² are each a number of 5 or more and may be identical to or different from each other, and p³ and p⁴ are each a number of 0 or more and may be identical to or different from each other.
X represents a hydrogen atom or a methyl group, and s is 0 to 200;
(C) an epoxy compound; and
(D) a curing catalyst,
wherein the first cyclic imide compound (A) is contained in an amount of 60 to 90 parts by mass and the second cyclic imide compound (B) is contained in an amount of 10 to 40 parts by mass per 100 parts by mass of a total of the first and second cyclic imide compounds (A) and (B).

In the resin composition according to the first aspect, the organic group represented by A in the formula (1) may be any one of tetravalent organic groups represented by the following structural formulae:

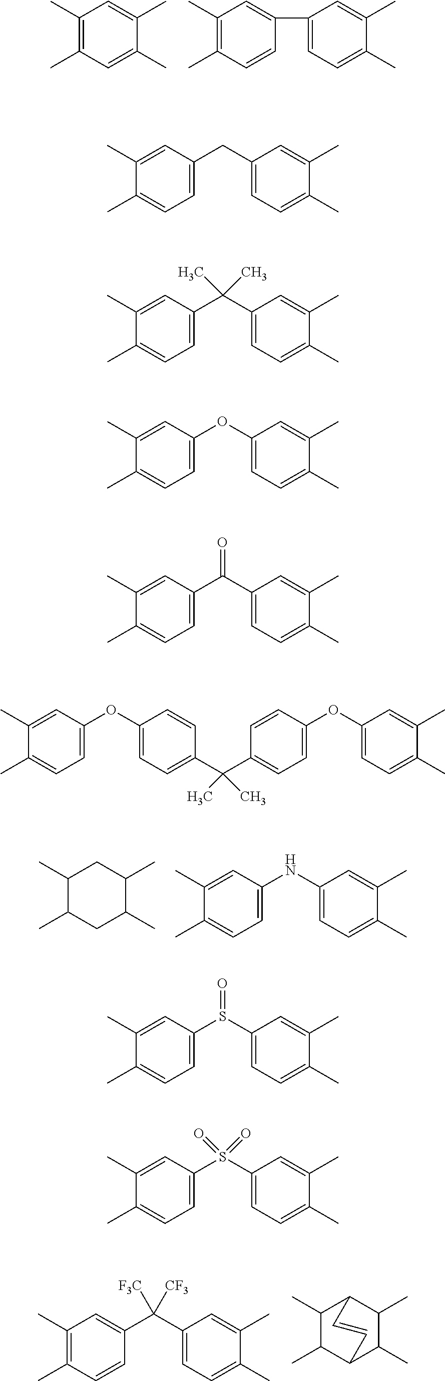

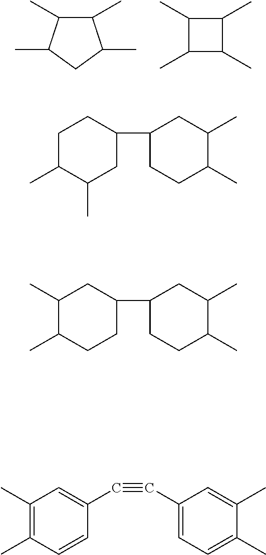

wherein bonds that are yet unbonded to substituent groups are to be bonded to carbonyl carbons forming the cyclic imide structures in the formula (1).

A prepreg according to a second aspect of the present invention contains the resin composition according to the first aspect.

A copper-clad laminate according to a third aspect of the present invention includes the prepreg according to the second aspect.

A printed-wiring board according to a fourth aspect of the present invention includes the copper-clad laminate according to the third aspect.

The resin composition according to the first aspect is a resin composition with low relative permittivity, low dielectric tangent, high adhesion (high peeling strength) to low-profile copper, high chemical resistance (high desmear treatment resistance), and high durability. Thus, the resin composition according to the first aspect is useful in applications such as base films, coverlay films, and semiconductor encapsulation materials for copper-clad laminates, printed-wiring boards, and flexible printed-wiring boards.

### DETAILED DESCRIPTION OF THE INVENTION

A resin composition according an embodiment of the present invention is described in detail hereunder.

### (A) Cyclic Imide Compound Represented by the Following Formula (1)

A first cyclic imide compound as a component (A) is an essential component of the resin composition according to the present invention and is represented by the following formula (1). Because the resin composition according to the present invention contains the component (A), a cured product of the resin composition has low relative permittivity, low dielectric tangent, and high chemical resistance.

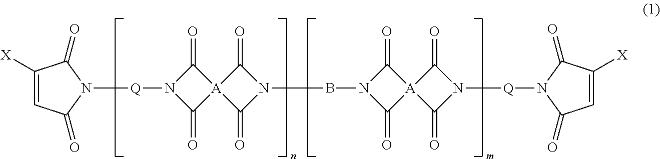

In the formula (1), A independently represents a tetravalent organic group having a cyclic structure, Q independently represents an alicyclic hydrocarbon group represented by the following formula (2):

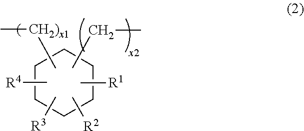

wherein R¹, R², R³, and R⁴ independently represent a hydrogen atom or an alkyl group having 1 to 5 carbon atoms, and x1 and x2 are each 0 to 4, B independently represents any one of divalent hydrocarbon groups represented by the following formulae:

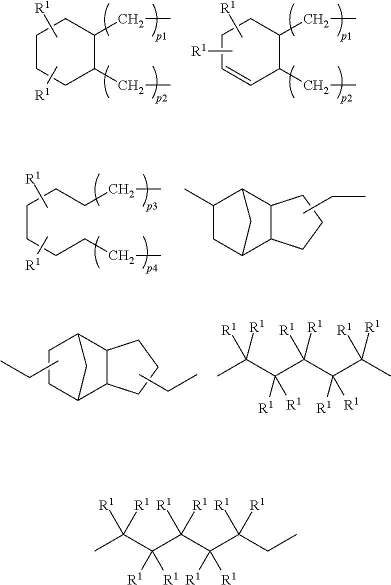

wherein bonds that are yet unbonded to substituent groups are to be bonded to nitrogen atoms forming cyclic imide structures in the formula (1), each R¹ independently represents a hydrogen atom or a linear or branched alkyl group having 1 to 20 carbon atoms, p¹ and p² are each a number of 5 or more and may be identical to or different from each other, and p³ and p⁴ are each a number of 0 or more and may be identical to or different from each other, and X represents a hydrogen atom or a methyl group, n is 1 to 200, m is 0 to 200, provided that when m is 1 or more, n:m=1:1 to 4:1, and repeating units identified by n and m are present in any order.

Here, the organic group represented by A in the formula (1) is independently a tetravalent organic group having a cyclic structure; particularly, it is preferred that Abe any one of tetravalent organic groups represented by the following structural formulae:

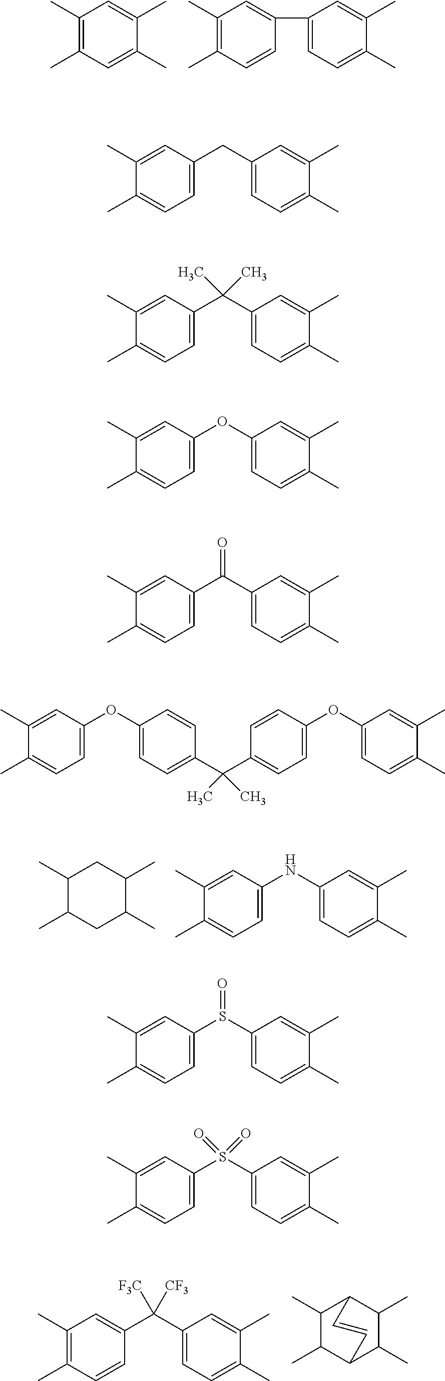

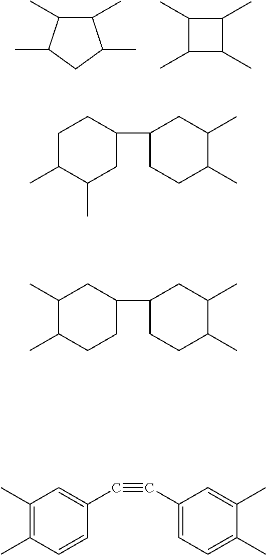

wherein bonds that are yet unbonded to substituent groups are to be bonded to carbonyl carbons forming the cyclic imide structures in the formula (1).

In the formula (1), Q independently represents an alicyclic hydrocarbon group represented by the formula (2).

In the formula (2), R¹, R², R³, and R⁴ independently represent a hydrogen atom or an alkyl group having 1 to 5 carbon atoms, preferably a hydrogen atom or an alkyl group having 1 to 3 carbon atoms, more preferably a hydrogen atom or a methyl group.

In the formula (2), x1 and x2 are each 0 to 4, preferably 0 to 2. x1 and x2 may be identical to or different from each other.

Specific examples of the formula (2) include the following structures.

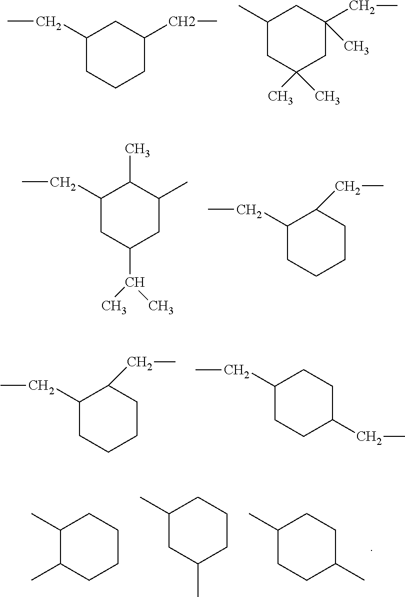

In the formula (1), B independently represents any one of divalent hydrocarbon groups represented by the following formulae:

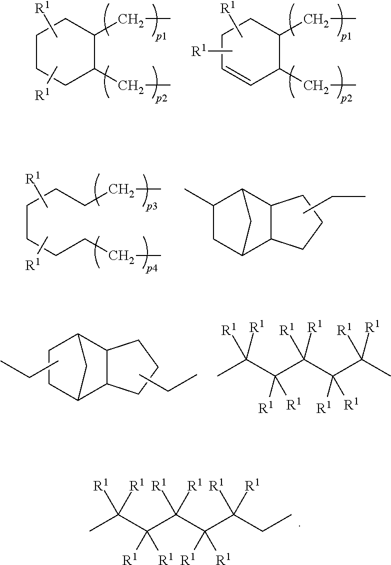

In the above structural formulae, bonds that are yet unbonded to substituent groups are to be bonded to the nitrogen atoms forming the cyclic imide structures in the formula (1).

In the above structural formulae, each R¹ independently represents a hydrogen atom or a linear or branched alkyl group having 1 to 20 carbon atoms. It is preferred that R¹ be a hydrogen atom or a linear or branched alkyl group having 1 to 10 carbon atoms, more preferably a hydrogen atom or a linear alkyl group having 1 to 10 carbon atoms.

In the above structural formulae, p¹ and p² are each a number of 5 or more, preferably a number of 5 to 12, more preferably a number of 6 to 10, and may be identical to or different from each other.

In the above structural formulae, p³ and p⁴ are each a number of 0 or more, preferably a number of 0 to 4, more preferably a number of 0 to 3, and may be identical to or different from each other.

A dimer acid frame-derived divalent hydrocarbon group is a group derived from dimer acid, which is a liquid fatty acid whose main component is a dicarboxylic acid having 36 carbon atoms and which is produced by dimerizing an unsaturated fatty acid having 18 carbon atoms and employing a natural substance such as a vegetable fat or oil as its raw material. Dimer acid is not a single type of frame, but may have multiple types of structures, and there exist several types of isomers. A dimer acid frame refers to a group derived from dimer diamine, which has a structure obtained by substituting carboxy groups in dimer acid with primary aminomethyl groups. As for the dimer acid frame-derived divalent hydrocarbon group, those having a structure with a reduced number of carbon-carbon double bonds in the dimer acid frame-derived hydrocarbon group due to a hydrogenation reaction are more preferred from the perspectives of heat resistance and reliability of a cured product.

In general, dimer acid may contain a trimer (trimer acid) because a natural substance such as a vegetable fat or oil is used as its raw material. It is preferred that, of the dimer acid-derived and trimer acid-derived hydrocarbon groups, the dimer acid-derived hydrocarbon group be contained in a high proportion, for example, 95% by mass or more, because such a composition has excellent dielectric properties, easily becomes less viscous when heated and thus exhibits excellent moldability, and tends to be less susceptible to moisture absorption.

As described above, a dimer acid frame may have multiple types of structures; therefore, in this specification, a dimer acid frame-derived divalent hydrocarbon group may be denoted by —C₃₆H₇₀— as its average structure.

In the formula (1), X represents a hydrogen atom or a methyl group, preferably a hydrogen atom.

In the formula (1), n is 1 to 200, preferably 2 to 100, more preferably 2 to 50.

In the formula (1), m is 0 to 200, preferably 1 to 50, more preferably 1 to 20.

When m is 1 or more, the ratio of n to m, n:m, is 1:1 to 4:1, preferably 1:1 to 3:1, more preferably 1:1 to 2:1. It is preferred that n:m be within these ranges because a cured product of the resin composition according to the present invention exhibits higher chemical resistance. In addition, repeating units identified by n and m may be present in any order.

While there are no particular restrictions on the weight average molecular weight (Mw) of the first cyclic imide compound as the component (A), it is preferred that the weight average molecular weight (Mw) be 500 to 1,000,000, more preferably 1,000 to 100,000, even more preferably 3,000 to 50,000. When the weight average molecular weight (Mw) is within these ranges, the resin composition has sufficient strength, and the cyclic imide groups at the ends can be efficiently reacted.

The term “weight average molecular weight (Mw)” as used herein refers to a weight average molecular weight measured by gel permeation chromatography (GPC) using polystyrene as a reference substance under the following conditions (the same applies hereinafter):

### [GPC Measurement Conditions]

Developing solvent: tetrahydrofuran

Flow rate: 0.6 mL/min

Column: TSK Guardcolumn Super H-L
TSKgel Super H4000 (6.0 mm I.D.×15 cm×1)
TSKgel Super H3000 (6.0 mm I.D.×15 cm×1)
TSKgel Super H2000 (6.0 mm I.D.×15 cm×2)
(all manufactured by Tosoh Corporation)

Column temperature: 40° C.

Sample injection volume: 20 L (tetrahydrofuran solution with sample concentration of 0.5% by mass)

Detector: differential refractive index detector (RI)

There are no particular restrictions on the method for producing the first cyclic imide compound as the component (A) (e.g., a maleimide compound or a citraconimide compound). For example, the cyclic imide compound may be produced by reacting an amine compound with an excessive amount of maleic anhydride or citraconic anhydride, or may be produced by reacting an acid anhydride with a diamine to synthesize an amine-terminated compound and then reacting the amine-terminated compound with an excessive amount of maleic anhydride or citraconic anhydride.

Examples of acid anhydrides include pyromellitic anhydride, maleic anhydride, succinic anhydride, 4,4′-carbonyldiphthalic anhydride, 4,4′-diphthalic anhydride, 4,4′-sulfonyldiphthalic anhydride, 4,4′-oxydiphthalic anhydride, and 4,4′-(4,4′-isopropylidenediphenoxy)diphthalic anhydride. Any one of these acid anhydrides may be used alone, or two or more of them may be used in combination, for example, depending on the purpose and use. It is preferred that the acid anhydride be pyromellitic anhydride, 4,4′-oxydiphthalic anhydride, or 4,4′-(4,4′-isopropylidenediphenoxy)diphthalic anhydride in terms of the electric properties of the cyclic imide compound.

Examples of diamines as the component that forms Q in the formula (1) include 1,3-di(aminomethyl)cyclohexane, 1-amino-4-(aminomethyl)cyclohexane, and isophoronediamine. Examples of diamines as the component that forms B in the formula (1) include tetramethyl-1,3-bis(3-aminopropyl)disiloxane, 1,12-diaminododecane, 1,10-diaminodecane, dimer diamine, octyldiamine, 1,3-di(aminomethyl)cyclohexane, isophoronediamine, 2,4,4-trimethylhexane-1,6-diamine, 2-methylpentane-1,5-diamine, and 3(4),8(9)-bis(aminomethyl)tricyclo[5.2.1.0(2,6)]decane. Any one of these diamines may be used alone, or two or more of them may be used in combination, for example, depending on the purpose and use. In terms of the electric properties of the cyclic imide compound, it is preferred that the diamine as the component that forms Q in the formula (1) be 1,3-di(aminomethyl)cyclohexane or isophoronediamine, and the diamine as the component that forms B in the formula (1) be tetramethyl-1,3-bis(3-aminopropyl)disiloxane, 1,12-diaminododecane, 1,3-diaminoadamantane, 1,10-diaminodecane, dimer diamine, octyldiamine, 2,4,4-trimethylhexane-1,6-diamine, or 2-methylpentane-1,5-diamine, and it is particularly preferred that the diamine as the component that forms Q in the formula (1) be isophoronediamine, and the diamine as the component that forms B in the formula (1) be dimer diamine.

The cyclic imide group equivalent of the component (A) is preferably 0.001 to 0.5 mol/100 g, more preferably 0.003 to 0.4 mol/100 g, even more preferably 0.01 to 0.3 mol/100 g, yet even more preferably 0.02 to 0.2 mol/100 g. It is preferred that the cyclic imide group equivalent be within these ranges because a cured product of the resin composition exhibits low relative permittivity, low dielectric tangent, and high adhesion.

The component (A) is added in an amount of 60 to 90 parts by mass, preferably 65 to 85 parts by mass, even more preferably 70 to 80 parts by mass. This is an amount per 100 parts by mass of a total of the component (A) and the component (B) described later. When the amount of the component (A) added is less than 60 parts by mass, the resin composition containing the component (A) may exhibit low chemical resistance and may cause peeling of copper when treated with a desmear solution. When the amount of the component (A) added is more than 90 parts by mass, the resin composition containing the component (A) may exhibit low adhesion to copper and may cause peeling of copper when via holes are formed with a laser or a drill.

One type of the first cyclic imide compound as the component (A) may be used alone, or two or more types thereof may be used in combination.

### (B) Cyclic Imide Compound Represented by the Following Formula (3)

A second cyclic imide compound as the component (B) is an essential component of the resin composition according to the present invention and is represented by the following formula (3). Because the resin composition according to the present invention contains the component (B), a cured product of the resin composition has low relative permittivity, low dielectric tangent, and high adhesion.

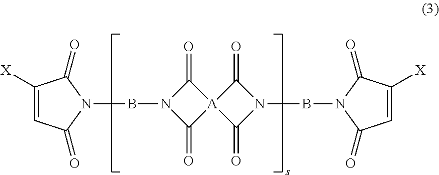

In the formula, A independently represents a tetravalent organic group having a cyclic structure, B independently represents any one of divalent hydrocarbon groups represented by the following formulae:

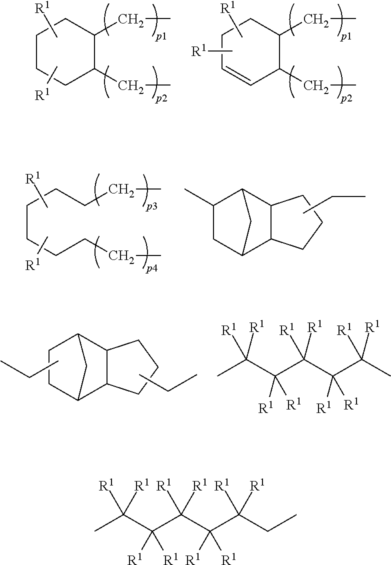

wherein bonds that are yet unbonded to substituent groups are to be bonded to nitrogen atoms forming cyclic imide structures in the formula (3), each R¹ independently represents a hydrogen atom or a linear or branched alkyl group having 1 to 20 carbon atoms, p¹ and p² are each a number of 5 or more and may be identical to or different from each other, and p³ and p⁴ are each a number of 0 or more and may be identical to or different from each other, and
X represents a hydrogen atom or a methyl group, and s is 0 to 200.

Here, the organic group represented by A in the formula (3) is independently a tetravalent organic group having a cyclic structure; particularly, it is preferred that A be any one of tetravalent organic groups represented by the following structural formulae:

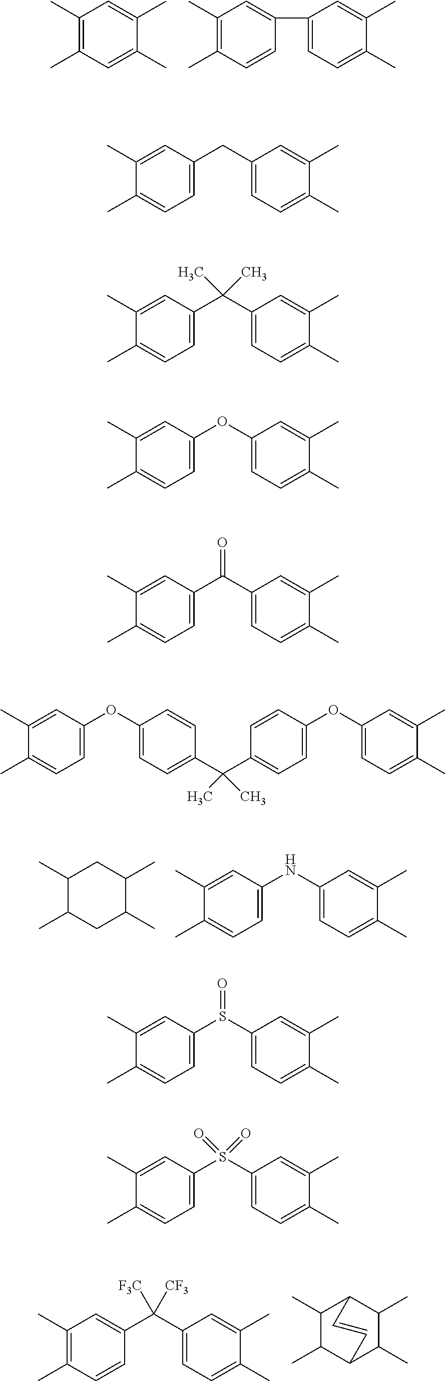

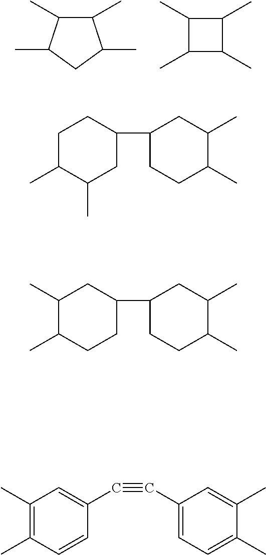

wherein bonds that are yet unbonded to substituent groups are to be bonded to carbonyl carbons forming the cyclic imide structures in the formula (3).

In the formula (3), B independently represents any one of divalent hydrocarbon groups represented by the following formulae:

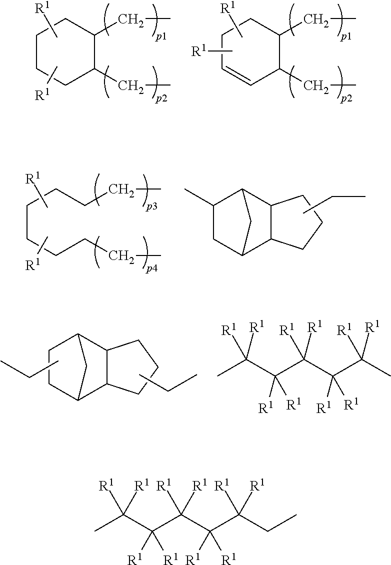

In the above structural formulae, bonds that are yet unbonded to substituent groups are to be bonded to nitrogen atoms forming the cyclic imide structures in the formula (3).

In the above structural formulae, each R¹ independently represents a hydrogen atom or a linear or branched alkyl group having 1 to 20 carbon atoms. R¹ is preferably a hydrogen atom or a linear or branched alkyl group having 1 to 10 carbon atoms, more preferably a hydrogen atom or a linear alkyl group having 1 to 10 carbon atoms.

In the above structural formulae, p¹ and p² are each a number of 5 or more, preferably a number of 5 to 12, more preferably a number of 6 to 10, and may be identical to or different from each other.

In the above structural formulae, p³ and p⁴ are each a number of 0 or more, preferably a number of 0 to 4, more preferably a number of 0 to 3, and may be identical to or different from each other.

In the formula (3), X represents a hydrogen atom or a methyl group, preferably a hydrogen atom.

In the formula (3), s is 0 to 200, preferably 0 to 100, more preferably 0 to 50.

While there are no particular restrictions on the weight average molecular weight (Mw) of the second cyclic imide compound as the component (B), it is preferred that the weight average molecular weight (Mw) be 500 to 1,000,000, more preferably 1,000 to 100,000, even more preferably 3,000 to 50,000. When the weight average molecular weight (Mw) is within these ranges, the resin composition has sufficient strength, and the cyclic imide groups at the ends can be efficiently reacted.

There are no particular restrictions on the method for producing the second cyclic imide compound as the component (B). For example, the cyclic imide compound may be produced by reacting an amine compound with an excessive amount of maleic anhydride or citraconic anhydride, or may be produced by reacting an acid anhydride with a diamine to synthesize an amine-terminated compound and then reacting the amine-terminated compound with an excessive amount of maleic anhydride or citraconic anhydride.

Examples of acid anhydrides include pyromellitic anhydride, maleic anhydride, succinic anhydride, 4,4′-carbonyldiphthalic anhydride, 4,4′-diphthalic anhydride, 4,4′-sulfonyldiphthalic anhydride, 4,4′-oxydiphthalic anhydride, and 4,4′-(4,4′-isopropylidenediphenoxy)diphthalic anhydride. Any one of these acid anhydrides may be used alone, or two or more of them may be used in combination, for example, depending on the purpose and use. It is preferred that the acid anhydride be pyromellitic anhydride, 4,4′-oxydiphthalic anhydride, or 4,4′-(4,4′-isopropylidenediphenoxy)diphthalic anhydride in terms of the electric properties of the cyclic imide compound.

Examples of diamines include tetramethyl-1,3-bis(3-aminopropyl)disiloxane, 1,12-diaminododecane, 1,10-diaminodecane, dimer diamine, octyldiamine, 2,4,4-trimethylhexane-1,6-diamine, 2-methylpentane-1,5-diamine, and 3(4),8(9)-bis(aminomethyl)tricyclo[5.2.1.0(2,6)]decane. Any one of these diamines may be used alone, or two or more of them may be used in combination, for example, depending on the purpose and use. In terms of the electric properties of the cyclic imide compound, it is preferred that the diamine be an aliphatic diamine such as tetramethyl-1,3-bis(3-aminopropyl)disiloxane, 1,12-diaminododecane, 1,10-diaminodecane, dimer diamine, octyldiamine, 1,3-di(aminomethyl)cyclohexane, 1,3-diaminoadamantane, 2,4,4-trimethylhexane-1,6-diamine, or 2-methylpentane-1,5-diamine, and it is particularly preferred that the diamine be dimer diamine or isophoronediamine.

The cyclic second imide compound as the component (B) may be a commercial product. Examples of commercial products include BMI-689, BMI-1500, and BMI-3000 (manufactured by Designer Molecules Inc.).

The cyclic imide group equivalent of the component (B) is preferably 0.001 to 0.5 mol/100 g, more preferably 0.003 to 0.4 mol/100 g, even more preferably 0.01 to 0.3 mol/100 g, yet even more preferably 0.02 to 0.2 mol/100 g. It is preferred that the cyclic imide group equivalent be within these ranges because a cured product of the resin composition exhibits low relative permittivity, low dielectric tangent, and high adhesion.

The component (B) is added in an amount of 10 to 40 parts by mass, preferably 15 to 35 parts by mass, more preferably 20 to 30 parts by mass. This is an amount per 100 parts by mass of a total of the component (A) described above and the component (B). When the amount of the component (B) added is less than 10 parts by mass, the resin composition containing the component (B) may exhibit low adhesion to copper and may cause peeling of copper when via holes are formed with a laser or a drill. When the amount of the component (B) added is more than 40 parts by mass, the resin composition containing the component (B) may exhibit low chemical resistance and may cause peeling of copper when treated with a desmear solution.

One type of the second cyclic imide compound as the component (B) may be used alone, or two or more types thereof may be used in combination.

It is preferred that the components (A) and (B) be contained in the resin composition according to the present invention in a total amount of 60% to 99% by mass, more preferably 65% to 95% by mass, even more preferably 70% to 95% by mass.

### (C) Epoxy Compound

An epoxy compound as a component (C) copolymerizes with the cyclic imide compounds as the components (A) and (B) and is an essential component of the resin composition according to the present invention. Copolymerization of epoxy groups with cyclic imide groups promotes curing of the cyclic imide groups so that higher adhesion can be achieved.

While there are no particular restrictions on the epoxy compound as the component (C), examples thereof include bisphenol A type epoxy compounds, bisphenol F type epoxy compounds, 3,3′,5,5′-tetramethyl-4,4′-biphenol type epoxy compounds, liquid polyfunctional epoxy compounds such as 4,4′-methylenebis(N,N-diglycidylaniline) and 4-glycidyloxy(N,N-diglycidylaniline), biphenol type epoxy compounds such as 4,4′-biphenol type epoxy compounds, biphenol novolac type epoxy compounds, biphenylaralkyl type epoxy compounds, phenol novolac type epoxy compounds, cresol novolac type epoxy compounds, bisphenol A novolac type epoxy compounds, naphthalenediol type epoxy compounds, trisphenylolmethane type epoxy compounds, tetrakisphenylolethane type epoxy compounds, phenol dicyclopentadiene novolac type epoxy compounds, and epoxy compounds obtained by hydrogenation of the aromatic rings of phenol dicyclopentadiene novolac type epoxy compounds. Of these, liquid polyfunctional epoxy compounds, biphenol novolac type epoxy compounds, phenol novolac type epoxy compounds, cresol novolac type epoxy compounds, bisphenol A novolac type epoxy compounds, biphenylaralkyl type epoxy compounds, and phenol dicyclopentadiene novolac type epoxy compounds are preferred. Any one of these epoxy compounds may be used alone, or two or more of them may be used in combination. If necessary, epoxy compounds other than those given above can also be used in certain amounts in combination depending on the purpose.

While there are no particular restrictions on the amount of the component (C) added, it is preferred that the component (C) be added in an amount of 0.1 to 20 parts by mass, more preferably 0.5 to 10 parts by mass, even more preferably 1 to 7 parts by mass, per 100 parts by mass of a total of the components (A) and (B). When the amount of the component (C) added is within these ranges, the resin composition can be sufficiently cured without adversely affecting the physical properties of the resin composition.

### (D) Curing Catalyst

A curing catalyst as a component (D) is an essential component of the resin composition according to the present invention. While there are no particular restrictions on the curing catalyst as the component (D), examples thereof include thermal radical polymerization initiators and thermal anionic polymerization initiators.

Examples of thermal radical polymerization initiators include organic peroxides such as methyl ethyl ketone peroxide, methylcyclohexanone peroxide, methyl acetoacetate peroxide, acetylacetone peroxide, 1,1-bis(t-butylperoxy)-3,3,5-trimethylcyclohexane, 1,1-bis(t-hexylperoxy)cyclohexane, 1,1-bis(t-hexylperoxy)-3,3,5-trimethylcyclohexane, 1,1-bis(t-butylperoxy)cyclohexane, 2,2-bis(4,4-di-t-butylperoxycyclohexyl)propane, 1,1-bis(t-butylperoxy)cyclododecane, n-butyl-4,4-bis(t-butylperoxy)valerate, 2,2-bis(t-butylperoxy)butane, 1,1-bis(t-butylperoxy)-2-methylcyclohexane, t-butyl hydroperoxide, p-menthane hydroperoxide, 1,1,3,3-tetramethylbutyl hydroperoxide, t-hexyl hydroperoxide, dicumyl peroxide, 2,5-dimethyl-2,5-bis(t-butylperoxy)hexane, α,α′-bis(t-butylperoxy)diisopropylbenzene, t-butylcumyl peroxide, di-t-butyl peroxide, 2,5-dimethyl-2,5-bis(t-butylperoxy)hexyne-3, isobutyryl peroxide, 3,5,5-trimethylhexanoyl peroxide, octanoyl peroxide, lauroyl peroxide, cinnamoyl peroxide, m-toluoyl peroxide, benzoyl peroxide, diisopropyl peroxydicarbonate, bis(4-t-butylcyclohexyl) peroxydicarbonate, di-3-methoxybutyl peroxydicarbonate, di-2-ethylhexyl peroxydicarbonate, di-sec-butyl peroxydicarbonate, di(3-methyl-3-methoxybutyl) peroxydicarbonate, di(4-t-butylcyclohexyl) peroxydicarbonate, α,α′-bis(neodecanoylperoxy)diisopropylbenzene, cumyl peroxyneodecanoate, 1,1,3,3-tetramethylbutyl peroxyneodecanoate, 1-cyclohexyl-1-methylethyl peroxyneodecanoate, t-hexyl peroxyneodecanoate, t-butyl peroxyneodecanoate, t-hexyl peroxypivalate, t-butyl peroxypivalate, 2,5-dimethyl-2,5-bis(2-ethylhexanoylperoxy)hexane, 1,1,3,3-tetramethylbutyl peroxy-2-ethylhexanoate, 1-cyclohexyl-1-methylethyl peroxy-2-ethylhexanoate, t-hexyl peroxy-2-ethylhexanoate, t-butyl peroxy-2-ethylhexanoate, t-butyl peroxyisobutyrate, t-butylperoxymaleic acid, t-butyl peroxylaurate, t-butyl peroxy-3,5,5-trimethylhexanoate, t-butylperoxyisopropyl monocarbonate, t-butyl peroxy-2-ethylhexyl monocarbonate, 2,5-dimethyl-2,5-bis(benzoylperoxy)hexane, t-butyl peroxyacetate, t-hexyl peroxybenzoate, t-butyl peroxy-m-toluoylbenzoate, t-butyl peroxybenzoate, bis(t-butylperoxy) isophthalate, t-butylperoxyallyl monocarbonate, and 3,3′,4,4′-tetra(t-butylperoxycarbonyl)benzophenone; and azo compounds such as 2,2′-azobis(N-butyl-2-methylpropionamide), 2,2′-azobis(N-cyclohexyl-2-methylpropionamide), 2,2′-azobis[N-(2-methylpropyl)-2-methylpropionamide], 2,2′-azobis[N-(2-methylethyl)-2-methylpropionamide], 2,2′-azobis(N-hexyl-2-methylpropionamide), 2,2′-azobis(N-propyl-2-methylpropionamide), 2,2′-azobis(N-ethyl-2-methylpropionamide), 2,2′-azobis[2-methyl-N-(2-hydroxyethyl)propionamide], 2,2′-azobis[N-(2-propenyl)-2-methylpropionamide], 2,2′-azobis{2-methyl-N-[1,1-bis(hydroxymethyl)-2-hydroxyethyl]propionamide}, 2,2′-azobis[N-(2-propenyl)-2-methylpropionamide], and dimethyl-1,1′-azobis(1-cyclohexanecarboxylate).

Examples of thermal anionic polymerization initiators include amine compounds such as triethylamine, triethylenediamine, 2-(dimethylaminomethyl)phenol, 1,8-diaza-bicyclo[5.4.0]undecene-7, tris(dimethylaminomethyl)phenol, and benzyldimethylamine; imidazole compounds such as 2-methylimidazole, 2-ethylimidazole, 2-phenylimidazole, 2-ethyl-4-methylimidazole, 2-undecylimidazole, 1-cyanoethyl-2-ethyl-4-methylimidazole, 2,4-diamino-6-[2-(2-methyl-1-imidazolyl)ethyl]-1,3,5-triazine, and 2-phenyl-4-hydroxy-5-methylimidazole; organophosphorus compounds such as triphenylphosphine, tributylphosphine, trioctylphosphine, tetrabutylphosphonium hexafluorophosphate, tetrabutylphosphonium tetraphenylborate, tetrabutylphosphonium acetate, tetraphenylphosphonium tetraphenylborate, tetraphenylphosphonium bromide, tetrabutylphosphonium bromide, tetrabutylphosphonium laurate, tetraphenylphosphonium hydrogen phthalate, bis(tetraphenylphosphonium) dihydrogen pyromellitate, and bis(tetrabutylphosphonium) dihydrogen pyromellitate.

Of these, thermal anionic polymerization initiators are preferred, and 2-ethyl-4-methylimidazole, 1-cyanoethyl-2-ethyl-4-methylimidazole, 2,4-diamino-6-[2-(2-methyl-1-imidazolyl)ethyl]-1,3,5-triazine, and 2-phenyl-4-hydroxy-5-methylimidazole are particularly preferred.

Any one of these polymerization initiators may be used alone, or two or more of them may be used in combination.

While there are no particular restrictions on the amount of the component (D) added, it is preferred that the component (D) be added in an amount of 0.01 to 10 parts by mass, more preferably 0.1 to 5 parts by mass, even more preferably 0.3 to 3 parts by mass, per 100 parts by mass of a total of the components (A) and (B). When the amount of the component (D) added is within these ranges, the resin composition can be sufficiently cured without adversely affecting the physical properties of the resin composition.

### Inorganic Filler

The resin composition according to the present invention may further contain an inorganic filler (component (E)).

While there are no particular restrictions on the inorganic filler, examples thereof include silica, metal oxides such as titanium dioxide, yttrium oxide, aluminum oxide, magnesium oxide, zinc oxide, and beryllium oxide; boron nitride, silicon nitride, and metal nitrides such as aluminum nitride; carbon-containing particles such as silicon carbide, diamond, and graphene; hollow particles such as silica balloons (hollow silica), carbon balloons, alumina balloons, and aluminosilicate balloons; elemental metals such as gold, silver, copper, palladium, aluminum, nickel, iron, cobalt, titanium, manganese, zinc, tungsten, platinum, lead, and tin; alloys such as solder, steel, and stainless steel; magnetic metal alloys such as stainless steel, Fe—Cr—Al—Si alloys, Fe—Si—Al alloys, Fe—Ni alloys, Fe—Cu—Si alloys, Fe—Si alloys, Fe—Si—B(—Cu—Nb) alloys, Fe—Si—Cr—Ni alloys, Fe—Si—Cr alloys, and Fe—Si—Al—Ni—Cr alloys; and ferrites such as hematite (Fe₂O₃), magnetite (Fe₃O₄), Mn—Zn-based ferrites, Ni—Zn-based ferrites, Mg—Mn-based ferrites, Zr—Mn-based ferrites, Ti—Mn-based ferrites, Mn—Zn—Cu-based ferrites, barium ferrite, and strontium ferrite. Any one of these may be used alone, or two or more of them may be used in combination.

By adding a metal oxide, a metal nitride, or carbon-containing particles, it is possible to decrease the coefficient of linear expansion and increase the thermal conductivity of a cured product of the resin composition. By adding hollow particles, it is possible to, for example, decrease the relative permittivity, dielectric tangent, and density of a cured product of the resin composition. By adding a metal or an alloy, it is possible to, for example, increase the electrical conductivity and thermal conductivity of a cured product of the resin composition. By adding a ferrite, it is possible to impart electromagnetic wave absorption capability to a cured product of the resin composition.

While there are no particular restrictions on the shape of the inorganic filler, the inorganic filler may be, for example, spherical, scaly, flaky, needle-shaped, rod-shaped, or oval. In particular, it is preferred that the inorganic filler be spherical, scaly, flaky, oval, or rod-shaped, and it is more preferred that the inorganic filler be spherical, scaly, flaky, or oval.

While there are no particular restrictions on the primary particle diameter of the inorganic filler, it is preferred that the median diameter measured with a laser diffraction particle size distribution analyzer be 0.05 to 500 μm, more preferably 0.1 to 300 μm, even more preferably 1 to 100 μm. It is preferred that the median diameter be within these ranges because the inorganic filler can be readily uniformly dispersed in the resin composition and does not settle, separate, or become unevenly distributed over time.

While there are no particular restrictions on the amount of the inorganic filler added, it is preferred that the inorganic filler be added in an amount of 5 to 3,000 parts by mass, more preferably 10 to 2,500 parts by mass, even more preferably 50 to 2,000 parts by mass, per 100 parts by mass of a total of the components (A) and (B) in the composition according to the present invention. When the amount of the inorganic filler added is within these ranges, the inorganic filler can provide its function sufficiently while maintaining the strength of the resin composition.

### Organic Filler

The resin composition according to the present invention may further contain an organic filler (component (F)).

While there are no particular restrictions on the organic filler, examples thereof include thermoplastic resin particles such as acrylic-butadiene copolymers, styrene-butadiene copolymers, acrylonitrile-styrene-butadiene copolymers, and acrylic block copolymers, carbon fiber, cellulose fiber, silicone powder, acrylic powder, polytetrafluoroethylene powder, polyethylene powder, and polypropylene powder. Any one of these may be used alone, or two or more of them may be used in combination.

While there are no particular restrictions on the shape of the organic filler, the organic filler may be, for example, spherical, fibrous, flaky, needle-shaped, rod-shaped, or oval. In particular, it is preferred that the organic filler be spherical, fibrous, flaky, oval, or rod-shaped, and it is more preferred that the organic filler be spherical, fibrous, flaky, or oval.

While there are no particular restrictions on the primary particle diameter of the organic filler, it is preferred that the median diameter measured with a laser diffraction particle size distribution analyzer be 0.05 to 500 μm, more preferably 0.1 to 300 μm, even more preferably 1 to 100 μm. It is preferred that the median diameter be within these ranges because the organic particles can be readily uniformly dispersed in the resin composition and do not settle, separate, or become unevenly distributed over time.

While there are no particular restrictions on the amount of the organic filler added, it is preferred that the organic filler be added in an amount of 1 to 400 parts by mass, more preferably 5 to 200 parts by mass, even more preferably 10 to 100 parts by mass, per 100 parts by mass of a total of the components (A) and (B) in the composition according to the present invention. When the amount of the organic filler added is within these ranges, the strength of the resin composition can be increased.

### Adhesion-Imparting Agent

The resin composition according to the present invention may contain an adhesion-imparting agent (component (G)) if necessary to attain adhesion or tack (pressure-sensitive adhesion). Examples of adhesion-imparting agents include acrylic resins, urethane resins, phenolic resins, terpene resins, and silane coupling agents. In particular, acrylic resins and silane coupling agents are preferred to impart adhesion, whereas terpene resins are preferred to impart tack (pressure-sensitive adhesion). One type of adhesion-imparting agent as the component (G) may be used alone, or two or more types thereof may be used in combination.

While there are no particular restrictions on acrylic resins, examples thereof include lauryl acrylate, stearyl acrylate, isostearyl acrylate, phenoxyethyl acrylate, phenoxydiethylene glycol acrylate, tetrahydrofurfuryl acrylate, isobornyl acrylate, 2-acryloyloxyethylphthalic acid, 2-acryloyloxyethyl acid phosphate, polyethylene glycol diacrylate, dimethyloltricyclodecane diacrylate, trimethylolpropane triacrylate, dipentaerythritol hexaacrylate, dioxane glycol diacrylate, 9,9-bis[4-(2-hydroxyethoxy)phenyl]fluorene diacrylate, lauryl methacrylate, phenoxyethyl methacrylate, phenoxydiethylene glycol methacrylate, tetrahydrofurfuryl methacrylate, isobornyl methacrylate, 2-methacryloyloxyethylphthalic acid, 2-methacryloyloxyethyl acid phosphate, polyethylene glycol dimethacrylate, and dimethyloltricyclodecane dimethacrylate.

While there are no particular restrictions on terpene resins, examples thereof include homopolymers of terpenes, including monoterpenes such as α-pinene, β-pinene, dipentene, and limonene, sesquiterpenes such as cedrene and farnesene, and diterpenes such as abietic acid, aromatic modified terpene resins that are copolymers of aromatic vinyl compounds such as styrene and α-methylstyrene with the above terpenes, and terpene phenol resins that are copolymers of phenols such as phenol, cresol, hydroquinone, naphthol, and bisphenol A with the above terpenes. Hydrogenated terpene resins obtained by hydrogenation of these terpene resins, for example, can also be used.

While there are no particular restrictions on silane coupling agents, examples thereof include silane coupling agents such as n-propyltrimethoxysilane, n-propyltriethoxysilane, n-octyltrimethoxysilane, n-octyltriethoxysilane, phenyltrimethoxysilane, phenyltriethoxysilane, methyltrimethoxysilane, methyltriethoxysilane, 2-[methoxy(polyethyleneoxy)propyl]-trimethoxysilane, methoxytri(ethyleneoxy)propyltrimethoxysilane, 3-glycidoxypropyltrimethoxysilane, 3-aminopropyltrimethoxysilane, N-phenyl-3-aminopropyltrimethoxysilane, 3-mercaptopropyltrimethoxysilane, 3-(methacryloyloxy)propyltrimethoxysilane, 3-isocyanatopropyltriethoxysilane, and 3-isocyanatopropyltrimethoxysilane.

While there are no particular restrictions on the amount of the adhesion-imparting agent added, it is preferred that the adhesion-imparting agent be added in an amount of 0.1 to 20 parts by mass, more preferably 0.5 to 10 parts by mass, even more preferably 1 to 5 parts by mass, per 100 parts by mass of a total of the components (A) and (B). When the amount of the adhesion-imparting agent added is within these ranges, the adhesion force or tack force of the resin composition can be further improved without altering the mechanical properties of the resin composition.

### Antioxidant

The resin composition according to the present invention may contain an antioxidant (component (H)) if necessary.

While there are no particular restrictions on the antioxidant, examples thereof include phenol-based antioxidants such as n-octadecyl-3-(3,5-di-t-butyl-4-hydroxyphenyl)propionate, n-octadecyl-3-(3,5-di-t-butyl-4-hydroxyphenyl)acetate, neododecyl-3-(3,5-di-t-butyl-4-hydroxyphenyl)propionate, dodecyl-p-(3,5-di-t-butyl-4-hydroxyphenyl)propionate, ethyl-α-(4-hydroxy-3,5-di-t-butylphenyl)isobutyrate, octadecyl-α-(4-hydroxy-3,5-di-t-butylphenyl)isobutyrate, octadecyl-α-(4-hydroxy-3,5-di-t-butyl-4-hydroxyphenyl)propionate, 2-(n-octylthio)ethyl-3,5-di-t-butyl-4-hydroxyphenylacetate, 2-(n-octadecylthio)ethyl-3,5-di-t-butyl-4-hydroxyphenylacetate, 2-(n-octadecylthio)ethyl-3-(3,5-di-t-butyl-4-hydroxyphenyl)propionate, 2-(2-stearoyloxyethylthio)ethyl-7-(3-methyl-5-t-butyl-4-hydroxyphenyl)heptanoate, 2-hydroxyethyl-7-(3-methyl-5-t-butyl-4-hydroxyphenyl)propionate, and pentaerythritol tetrakis[3-(3,5-di-t-butyl-4-hydroxyphenyl)propionate]; sulfur-based antioxidants such as dilauryl-3,3′-thiodipropionate, dimyristyl-3,3′-thiodipropionate, distearyl-3,3′-thiodipropionate, ditridecyl-3,3′-thiodipropionate, and pentaerythrityl tetrakis(3-laurylthiopropionate); and phosphorus-based antioxidants such as tridecyl phosphite, triphenyl phosphite, tris(2,4-di-t-butylphenyl) phosphite, 2-ethylhexyl diphenyl phosphite, diphenyl tridecyl phosphite, 2,2-methylenebis(4,6-di-t-butylphenyl)octyl phosphite, distearyl pentaerythritol diphosphite, bis(2,6-di-t-butyl-4-methylphenyl)pentaerythritol diphosphite, and 2-[[2,4,8,10-tetrakis(1,1-dimethylethyl)dibenzo[d,f][1,3,2]dioxaphosphepin-6-yl]oxy]-N,N-bis[2-[[2,4,8,10-tetrakis(1,1-dimethylethyl)dibenzo[d,f][1,3,2]dioxaphosphepin-6-yl]oxy]-ethyl]ethanamine. One type of antioxidant as the component (H) may be used alone, or two or more types thereof may be used in combination.

While there are no particular restrictions on the amount of the antioxidant added, it is preferred that the antioxidant be added in an amount of 0.00001 to 5 parts by mass, more preferably 0.0001 to 4 parts by mass, even more preferably 0.001 to 3 parts by mass, per 100 parts by mass of a total of the components (A) and (B). When the amount of the antioxidant added is within these ranges, the oxidation of the resin composition can be inhibited without altering the mechanical properties of the resin composition.

### Flame Retardant

The resin composition according to the present invention may contain a flame retardant (component (I)) if necessary to attain flame retardancy.

While there are no particular restrictions on the flame retardant, examples thereof include phosphorus-based flame retardants, metal hydrates, halogen-based flame retardants, and guanidine-based flame retardants. Examples of phosphorus-based flame retardants include red phosphorus, ammonium phosphates such as monoammonium phosphate, diammonium phosphate, triammonium phosphate, and ammonium polyphosphate, inorganic nitrogen-containing phosphorus compounds such as guanidine phosphate and phosphoramides, phosphoric acid, phosphine oxides, triphenyl phosphate, tricresyl phosphate, trixylenyl phosphate, cresyl diphenyl phosphate, cresyl di-2,6-xylenyl phosphate, resorcinol bis(diphenyl phosphate), 1,3-phenylene bis(di-2,6-xylenyl phosphate), bisphenol A-bis(diphenyl phosphate), 1,3-phenylene bis(diphenyl phosphate), divinyl phenylphosphonate, diallyl phenylphosphonate, bis(1-butenyl) phenylphosphonate, phenyl diphenylphosphinate, methyl diphenylphosphinate, phosphazene compounds such as bis(2-allylphenoxy)phosphazene and dicresyl phosphazene, melamine phosphate, melamine pyrophosphate, melamine polyphosphate, melam polyphosphate, melem polyphosphate, 9,10-dihydro-9-oxa-10-phosphaphenanthrene-10-oxide, and 10-(2,5-dihydroxyphenyl)-9,10-dihydro-9-oxa-10-phosphaphenanthrene-10-oxide. Examples of metal hydrates include aluminum hydroxide hydrate and magnesium hydroxide hydrate. Examples of halogen-based flame retardants include hexabromobenzene, pentabromotoluene, ethylenebis(pentabromophenyl), ethylenebistetrabromophthalimide, 1,2-dibromo-4-(1,2-dibromoethyl)cyclohexane, tetrabromocyclooctane, hexabromocyclododecane, bis(tribromophenoxy)ethane, brominated polyphenylene ether, brominated polystyrene, and 2,4,6-tris(tribromophenoxy)-1,3,5-triazine. Examples of guanidine-based flame retardants include guanidine sulfamate and guanidine phosphate. One type of flame retardant as the component (I) may be used alone, or two or more types thereof may be used in combination.

While there are no particular restrictions on the amount of the flame retardant added, it is preferred that the flame retardant be added in an amount of 0.01 to 5 parts by mass, more preferably 0.05 to 4 parts by mass, even more preferably 0.1 to 3 parts by mass, per 100 parts by mass of a total of the components (A) and (B). When the amount of the flame retardant added is within these ranges, flame retardancy can be imparted to the resin composition without altering the mechanical properties of the resin composition.

### Production Method

As a method for producing the resin composition according to the present invention, there may be employed, for example, a method where the components (A) to (D) as well as the other additives that are added if necessary are mixed by, for example, a planetary mixer (manufactured by Inoue Mfg., Inc.) or a mixer “Thinky Conditioning Mixer” (manufactured by Thinky Corporation), preferably a method where an organic solvent (e.g., cyclopentanone, cyclohexanone, mesitylene, anisole, dibutyl ether, diphenyl ether, 1,4-dioxane, N,N-dimethylformamide, N,N-dimethylacetamide, dimethyl sulfoxide, or N-methylpyrrolidone) is further added and mixed. By adding an organic solvent, it is possible to reduce the viscosity of the resin composition so that the components can be more uniformly mixed together. While the organic solvent may be distilled away under reduced pressure after mixing to obtain the resin composition, the mixture may be directly used without distillation or may be used with its concentration adjusted to the desired level, for example, when used as a prepreg.

### Prepreg

The resin composition according to the present invention can also be used as a prepreg by dissolving the resin composition in the organic solvent described above, impregnating a fiber base material therewith, and drying the fiber base material by heating.

As the fiber base material, known fiber base materials used for laminates can be used. Examples of fiber base materials include inorganic fibers such as E glass, S glass, T glass, NE glass, and Q glass (quartz glass); and organic fibers such as polyethylene, polyesters, polyamides, and polytetrafluoroethylene. Any one of these may be used alone, or two or more of them may be used in combination. Of these, in terms of dielectric properties, inorganic fibers are preferred, and T glass, NE glass, and Q glass are more preferred.

While there are no particular restrictions on the thickness of the fiber base material, it is preferred that the thickness of the fiber base material be 5 to 500 μm, more preferably 10 to 100 μm, even more preferably 20 to 80 μm. When the thickness of the fiber base material is within these ranges, a prepreg with excellent flexibility, low warpage, and high strength can be obtained.

These fiber base materials may be heated or surface-treated with a silane coupling agent or other material to improve the dielectric properties and the affinity with resins.

While there are no particular restrictions on the amount of the resin composition contained in the prepreg, it is preferred that the resin composition be contained in an amount of 20% to 90% by volume, more preferably 30% to 80% by volume, even more preferably 40% to 70% by volume. When the amount of the resin composition contained is within these ranges, the adhesion strength to conductors can be increased while maintaining the dielectric properties and low warpage.

While there are no particular restrictions on the thickness of the prepreg according to the present invention, it is preferred that the thickness of the prepreg be 10 to 500 μm, more preferably 25 to 300 μm, even more preferably 40 to 200 μm. When the thickness of the prepreg is within these ranges, a copper-clad laminate can be well produced.

The prepreg according to the present invention may be semi-cured (B-staged) by heating in advance. While there are no particular restrictions on the method for B-staging, B-staging can be performed, for example, by dissolving the resin composition according to the present invention in a solvent, impregnating a fiber base material therewith, drying the fiber base material, and heating the fiber base material at a temperature of 80° C. to 200° C. for 1 to 30 minutes.

### Copper-Clad Laminate

The prepreg according to the present invention may also be used as a copper-clad laminate by stacking the prepreg and a copper foil and pressing them together while curing the prepreg by heating.

While there are no particular restrictions on the method for producing the copper-clad laminate, the copper-clad laminate can be produced, for example, using 1 to 20, preferably 2 to 10, pieces of the prepreg by pressing together the prepreg and a copper foil placed on one or both sides thereof while curing the prepreg by heating.

While there are no particular restrictions on the thickness of the copper foil, it is preferred that the thickness of the copper foil be 3 to 70 μm, more preferably 10 to 50 μm, even more preferably 15 to 40 μm. When the thickness of the copper foil is within these ranges, a multilayer copper-clad laminate with high reliability can be formed.

While there are no particular restrictions on the molding conditions for the copper-clad laminate, the copper-clad laminate can be formed, for example, using a multistage press, a multistage vacuum press, a continuous molding machine, an autoclave molding machine, or the like at a temperature of 100° C. to 400° C. and a pressure of 1 to 100 MPa for a heating time of 0.1 to 4 hours. The prepreg according to the present invention can also be molded together with a copper foil and a wiring board for an inner layer to form a copper-clad laminate.

### Printed-Wiring Board

The copper-clad laminate according to the present invention may also be used as a printed-wiring board by performing circuit processing.

While there are no particular restrictions on the method for circuit processing, circuit formation processing may be performed, for example, by drilling, metal plating, and metal foil etching.

A printed-wiring board may also be produced by a build-up method in which the resin composition or prepreg according to the present invention and a copper foil are sequentially stacked.

### Working Examples

The present invention is described in greater detail hereunder with reference to working and comparative examples; the present invention should not be limited to the following working examples.

The molecular weight shown in the following examples is a weight average molecular weight (Mw) measured by gel permeation chromatography (GPC) using polystyrene as a reference substance. The measurement conditions are given below:

### [GPC Measurement Conditions]

Developing solvent: tetrahydrofuran

Flow rate: 0.6 mL/min

Column: TSK Guardcolumn Super H-L
TSKgel Super H4000 (6.0 mm I.D.×15 cm×1)
TSKgel Super H3000 (6.0 mm I.D.×15 cm×1)
TSKgel Super H2000 (6.0 mm I.D.×15 cm×2)
(all manufactured by Tosoh Corporation)

Column temperature: 40° C.

Sample injection volume: 20 L (tetrahydrofuran solution with sample concentration of 0.5% by mass)

Detector: differential refractive index detector (RI)

### (A) First Cyclic Imide Compound

### (A-1)

To 263 g of N-methylpyrrolidone were added 114 g (1.0 mol) of 1,4-cyclohexanediamine and 499 g (0.96 mol) of 4,4′-(4,4′-isopropylidenediphenoxy)diphthalic anhydride, followed by stirring at 25° C. for 3 hours. Then, stirring was further performed at 150° C. for 5 hours. To the resulting solution were added 196 g (2.0 mol) of maleic anhydride, 82 g (1.0 mol) of sodium acetate, and 204 g (2.0 mol) of acetic anhydride, followed by stirring at 80° C. for 1 hour. Then, 500 g of toluene was added, and after washing with water and removal of water, the solvent was distilled away under reduced pressure to obtain bismaleimide (A-1) represented by the following formula (weight average molecular weight: 18,000, maleimide equivalent: 0.011 mol/100 g):

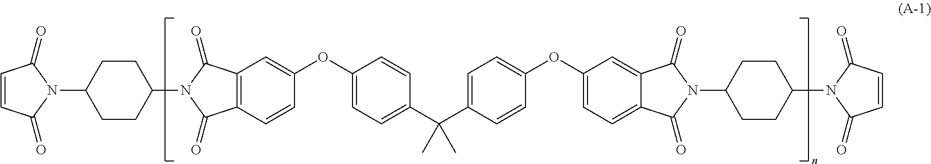

wherein n≈30 (average value).

### (A-2)

To 263 g of N-methylpyrrolidone were added 113 g (0.67 mol) of isophoronediamine, 174 g (0.33 mol) of dimer diamine, and 209 g (0.96 mol) of pyromellitic anhydride, followed by stirring at 25° C. for 3 hours. Then, stirring was further performed at 150° C. for 5 hours. To the resulting solution were added 196 g (2.0 mol) of maleic anhydride, 82 g (1.0 mol) of sodium acetate, and 204 g (2.0 mol) of acetic anhydride, followed by stirring at 80° C. for 1 hour. Then, 500 g of toluene was added, and after washing with water and removal of water, the solvent was distilled away under reduced pressure to obtain bismaleimide (A-2) represented by the following formula (weight average molecular weight: 15,000, maleimide equivalent: 0.013 mol/100 g):

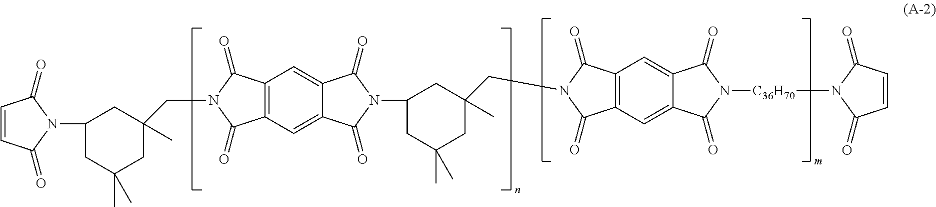

wherein n≈20 (average value), and m≈10 (average value).

### (A-3)

To 263 g of N-methylpyrrolidone were added 136 g (0.80 mol) of isophoronediamine, 104 g (0.20 mol) of dimer diamine, and 298 g (0.96 mol) of 4,4′-diphthalic anhydride, followed by stirring at 25° C. for 3 hours. Then, stirring was further performed at 150° C. for 5 hours. To the resulting solution were added 196 g (2.0 mol) of maleic anhydride, 82 g (1.0 mol) of sodium acetate, and 204 g (2.0 mol) of acetic anhydride, followed by stirring at 80° C. for 1 hour. Then, 500 g of toluene was added, and after washing with water and removal of water, the solvent was distilled away under reduced pressure to obtain bismaleimide (A-3) represented by the following formula (weight average molecular weight: 21,000, maleimide equivalent: 0.0095 mol/100 g):

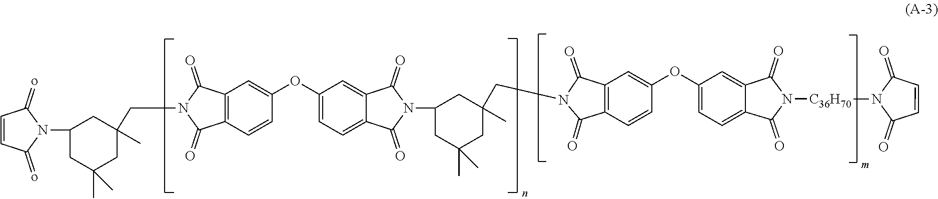

wherein n≈32 (average value), and m≈8 (average value).

### (A′-1)

To 263 g of N-methylpyrrolidone were added 100 g (0.5 mol) of dodecanediamine, 264 g (0.5 mol) of dimer diamine, and 298 g (0.96 mol) of 4,4′-oxydiphthalic anhydride, followed by stirring at 25° C. for 3 hours. Then, stirring was further performed at 150° C. for 5 hours. To the resulting solution were added 196 g (2.0 mol) of maleic anhydride, 82 g (1.0 mol) of sodium acetate, and 204 g (2.0 mol) of acetic anhydride, followed by stirring at 80° C. for 1 hour. Then, 500 g of toluene was added, and after washing with water and removal of water, the solvent was distilled away under reduced pressure to obtain bismaleimide (A′-1) represented by the following formula (weight average molecular weight: 13,000, maleimide equivalent: 0.015 mol/100 g):

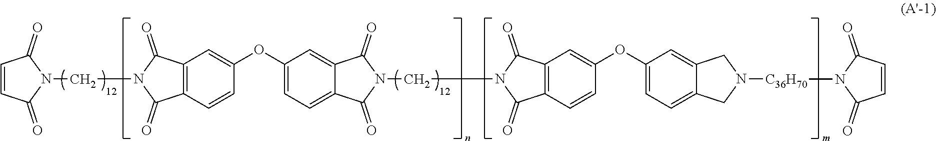

wherein n≈10 (average value), and m≈10 (average value).

### (A′-2)

To 263 g of N-methylpyrrolidone were added 206 g (0.67 mol) of 3,3′,5,5′-tetraethyl-4,4′-diaminodiphenylmethane, 174 g (0.33 mol) of dimer diamine, and 298 g (0.96 mol) of 4,4′-oxydiphthalic anhydride, followed by stirring at 25° C. for 3 hours. Then, stirring was further performed at 150° C. for 5 hours. To the resulting solution were added 196 g (2.0 mol) of maleic anhydride, 82 g (1.0 mol) of sodium acetate, and 204 g (2.0 mol) of acetic anhydride, followed by stirring at 80° C. for 1 hour. Then, 500 g of toluene was added, and after washing with water and removal of water, the solvent was distilled away under reduced pressure to obtain bismaleimide (A′-2) represented by the following formula (weight average molecular weight: 20,000, maleimide equivalent: 0.010 mol/100 g):

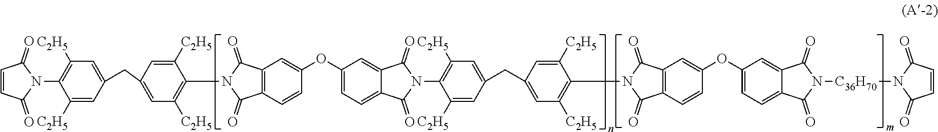

wherein n≈20 (average value), and m≈10 (average value).

### (A′-3)

To 263 g of N-methylpyrrolidone were added 101 g (0.33 mol) of 3,3′,5,5′-tetraethyl-4,4′-diaminodiphenylmethane, 353 g (0.67 mol) of dimer diamine, and 298 g (0.96 mol) of 4,4′-oxydiphthalic anhydride, followed by stirring at 25° C. for 3 hours. Then, stirring was further performed at 150° C. for 5 hours. To the resulting solution were added 196 g (2.0 mol) of maleic anhydride, 82 g (1.0 mol) of sodium acetate, and 204 g (2.0 mol) of acetic anhydride, followed by stirring at 80° C. for 1 hour. Then, 500 g of toluene was added, and after washing with water and removal of water, the solvent was distilled away under reduced pressure to obtain bismaleimide (A′-3) represented by the following formula (weight average molecular weight: 23,000, maleimide equivalent: 0.0087 mol/100 g):

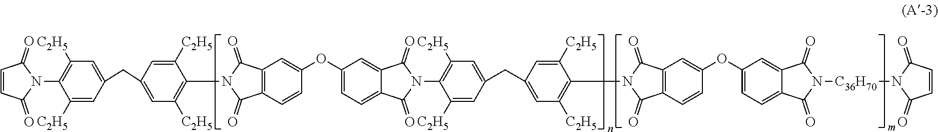

wherein n≈10 (average value), and m≈20 (average value).

### (B) Second Cyclic Imide Compound

### (B-1)

Maleimide compound represented by the following formula (BMI-3000, manufactured by Designer Molecules Inc.) (weight average molecular weight: 10,000, maleimide equivalent: 0.020 mol/100 g):

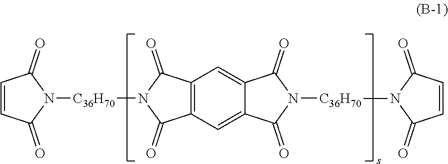

wherein s≈18 (average value).

### (B-2)

Maleimide compound represented by the following formula (BMI-1500, manufactured by Designer Molecules Inc.) (weight average molecular weight: 3,000, maleimide equivalent: 0.067 mol/100 g)

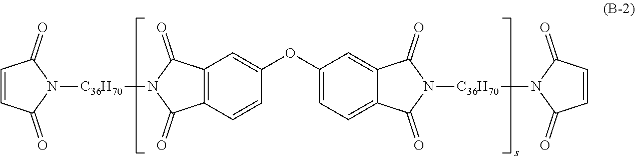

wherein s≈4 (average value).

### (B-3)

Maleimide compound represented by the following formula (BMI-689, manufactured by Designer Molecules Inc.) (weight average molecular weight: 700, maleimide equivalent: 0.29 mol/100 g)

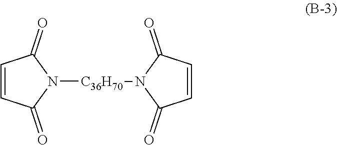

### (C) Epoxy Compound

(C-1) Biphenylaralkyl type epoxy resin (trade name “NC-3000” (manufactured by Nippon Kayaku Co., Ltd.)
(C-2) Bisphenol A type epoxy resin (trade name “jER-828EL” (manufactured by Mitsubishi Chemical Corporation)

### (D) Curing Catalyst

(D-1) 2-Ethyl-4-methylimidazole

### (E) Inorganic Filler

(E-1) Silica “SFP-130MC” (median diameter of primary particles: 0.6 μm) (manufactured by Denka Company Limited)

### (F) Organic Filler

(F-1) Silicone powder “KMP-600” (median diameter of primary particles: 5 μm) (manufactured by Shin-Etsu Chemical Co., Ltd.)

### (G) Adhesion-Imparting Agent

(G-1) Silane coupling agent (3-glycidoxypropyltrimethoxysilane, trade name “KBM-403”, manufactured by Shin-Etsu Chemical Co., Ltd.)

### (H) Antioxidant

(H-1) Pentaerythritol tetrakis[3-(3,5-di-t-butyl-4-hydroxyphenyl)propionate](trade name “ADK STAB AO-60”, manufactured by ADEKA corporation)

### (I) Flame Retardant

(I-1) Guanidine phosphate (trade name “APINON-303”, manufactured by Sanwa Chemical Co., Ltd.)

### Method for Preparing Resin Composition

For each of Working Examples 1 to 12 and Comparative Examples 1 to 7, in addition to the composition (in parts by mass) shown in Table 1 or 2, cyclopentanone was added and mixed in an amount of 100 parts by mass per 100 parts by mass of a total of the individual components. The mixture was kneaded in a planetary mixer (manufactured by Inoue Mfg., Inc.) at 80° C. for 30 minutes, followed by cooling to 25° C. The resulting solution was transferred to a flask, and the solvent was distilled away under reduced pressure to prepare a resin composition.

### Relative Permittivity and Dielectric Tangent

The prepared resin composition was placed in a mold having a size of 30 mm×40 mm×100 μm in thickness and was press-cured at 180° C. and 3 MPa for 1 hour to produce a test sample. A network analyzer (E5063-2D5 manufactured by Keysight Technologies) and a stripline (manufactured by KEYCOM Corporation) were connected to the produced test sample, and the relative permittivity and the dielectric tangent were measured at a frequency of 10 GHz. The results are shown in Tables 1 and 2.

### Peeling Strength

The resin composition prepared in the above manner was applied in film form to produce a resin film with a thickness of 25 μm, and a stainless steel sheet, the resin film, and a copper foil (trade name: TQ-M4-VSP, manufactured by Mitsui Mining & Smelting Co., Ltd.) with a thickness of 18 μm were stacked in that order and press-cured at 180° C. and 3 MPa for 1 hour to produce a test sample. The force (peeling strength) at which the copper foil peeled from the resin film was determined using a tensile tester (manufactured Toyo Seiki Seisaku-sho, Ltd., trade name: Strograph VE-1D) in accordance with JIS-C-6481:1996, which is a test standard for copper-clad laminates for printed-wiring boards, at a width of 10 mm and a speed of 50 mm/min in a 900 direction. The results are shown in Tables 1 and 2.

### Desmear Treatment Resistance

The prepared resin composition was placed in a mold having a size of 30 mm×40 mm×100 μm in thickness and was press-cured at 180° C. and 3 MPa for 1 hour to produce a test sample. The weight reduction ratio of the produced test sample after desmear treatment was calculated (amount of mass reduction (g)/surface area of test piece (dm²)). The desmear treatment was performed in the following order: swelling (at 70° C. for 5 minutes), roughening (at 80° C. for 10 minutes), neutralization (at 40° C. for 5 minutes), and washing with water (at room temperature for 5 minutes). The test solutions used were a swelling solution, a desmear solution, and a neutralization solution manufactured by Atotech whose concentrations were adjusted to predetermined levels. The results are shown in Tables 1 and 2.

TABLE 1

| | | | Working | Working | Working | Working | Working | Working |
|---|---|---|---|---|---|---|---|---|
| | | | Example 1 | Example 2 | Example 3 | Example 4 | Example 5 | Example 6 |
| (A) | (A-1) | | 65 | | | 85 | 85 | 40 |
| | (A-2) | | | 65 | | | | |
| | (A-3) | | | | 65 | | | 40 |
| (B) | (B-1) | | 35 | | | 15 | 15 | 20 |
| | (B-2) | | | 35 | | | | |
| | (B-3) | | | | 35 | | | |
| (C) | (C-1) | | 7 | 7 | 7 | 7 | 4 | 4 |
| | (C-2) | | | | | | | |
| (D) | (D-1) | | 1 | 1 | 1 | 1 | 2 | 2 |
| (E) | (E-1) | | | | | | | |
| (F) | (F-1) | | | | | | | |
| (G) | (G-1) | | | | | | | |
| (H) | (H-1) | | | | | | | |
| (I) | (I-1) | | | | | | | |
| Evaluation | Relative | | 2.5 | 2.5 | 2.6 | 2.6 | 2.6 | 2.6 |
| results | permittivity | | | | | | | |
| | (10 GHz) | | | | | | | |
| | Dielectric | | 0.0016 | 0.0017 | 0.0021 | 0.0022 | 0.0020 | 0.0020 |
| | tangent | | | | | | | |
| | (10 GHz) | | | | | | | |
| | Peeling | kN/m | 1.2 | 1.2 | 1.0 | 0.8 | 0.8 | 0.9 |
| | strength | | | | | | | |
| | Desmear | g/dm² | 0.011 | 0.010 | 0.010 | 0.007 | 0.007 | 0.008 |
| | resistance | | | | | | | |

| | | | Working | Working | Working | Working | Working | Working |
|---|---|---|---|---|---|---|---|---|
| | | | Example 7 | Example 8 | Example 9 | Example 10 | Example 11 | Example 12 |
| (A) | (A-1) | | 90 | 60 | 65 | 65 | 65 | 65 |
| | (A-2) | | | | | | | |
| | (A-3) | | | | | | | |
| (B) | (B-1) | | 10 | 40 | 35 | 35 | 35 | 35 |
| | (B-2) | | | | | | | |
| | (B-3) | | | | | | | |
| (C) | (C-1) | | 7 | 7 | | 7 | 7 | 7 |
| | (C-2) | | | | 7 | | | |
| (D) | (D-1) | | 1 | 1 | 1 | 1 | 1 | 1 |
| (E) | (E-1) | | | | | 300 | | |
| (F) | (F-1) | | | | | | 50 | |
| (G) | (G-1) | | | | | | 3 | |
| (H) | (H-1) | | | | | | | 2 |
| (I) | (I-1) | | | | | | | 2 |
| Evaluation | Relative | | 2.6 | 2.4 | 2.5 | 2.9 | 2.8 | 2.6 |
| results | permittivity | | | | | | | |
| | (10 GHz) | | | | | | | |
| | Dielectric | | 0.0024 | 0.0015 | 0.0016 | 0.0012 | 0.0022 | 0.0019 |
| | tangent | | | | | | | |
| | (10 GHz) | | | | | | | |
| | Peeling | kN/m | 0.7 | 1.3 | 1.2 | 0.9 | 1.0 | 1.1 |
| | strength | | | | | | | |
| | Desmear | g/dm² | 0.007 | 0.020 | 0.010 | 0.012 | 0.008 | 0.010 |
| | resistance | | | | | | | |

TABLE 2

| | | | Comparative | Comparative | Comparative | Comparative | Comparative | Comparative | Comparative |
|---|---|---|---|---|---|---|---|---|---|
| | | | Example 1 | Example 2 | Example 3 | Example 4 | Example 5 | Example 6 | Example 7 |
| (A) | (A-1) | | | | | 100 | | 95 | 50 |
| | (A-2) | | | | | | | | |
| | (A-3) | | | | | | | | |
| | (A′-1) | | 65 | | | | | | |
| | (A′-2) | | | 65 | | | | | |
| | (A′-3) | | | | 65 | | | | |
| (B) | (B-1) | | 35 | 35 | 35 | | 100 | 5 | 50 |
| | (B-2) | | | | | | | | |
| | (B-3) | | | | | | | | |
| (C) | (C-1) | | 7 | 7 | 7 | 7 | 7 | 7 | 7 |
| | (C-2) | | | | | | | | |
| (D) | (D-1) | | 1 | 1 | 1 | 1 | 1 | 1 | 1 |
| (E) | (E-1) | | | | | | | | |
| (F) | (F-1) | | | | | | | | |
| (G) | (G-1) | | | | | | | | |
| (H) | (H-1) | | | | | | | | |
| (I) | (I-1) | | | | | | | | |
| Evaluation | Relative | | 2.5 | 2.9 | 2.7 | 2.5 | 2.5 | 2.6 | 2.5 |
| results | permittivity | | | | | | | | |
| | (10 GHz) | | | | | | | | |
| | Dielectric | | 0.0023 | 0.0051 | 0.0035 | 0.0021 | 0.0015 | 0.0021 | 0.0017 |
| | tangent | | | | | | | | |
| | (10 GHz) | | | | | | | | |
| | Peeling | kN/m | 1.3 | 1.3 | 1.3 | 0.5 | 1.6 | 0.6 | 1.4 |
| | strength | | | | | | | | |
| | Desmear | g/dm² | 0.100 | 0.007 | 0.050 | 0.007 | 0.300 | 0.007 | 0.200 |
| | resistance | | | | | | | | |

The cured products of Working Examples 1 to 12 had low relative permittivity, low dielectric tangent, high peeling strength (high adhesion to low-profile copper), and sufficient desmear treatment resistance.

In Comparative Example 1, the desmear treatment resistance was low because the group corresponding to Q in the formula (1) of the component (A) was a linear hydrocarbon group.

In Comparative Examples 2 and 3, the value of the dielectric tangent was high because the group corresponding to Q in the formula (1) of the component (A) was an aromatic hydrocarbon group.

In Comparative Examples 4 and 6, the peeling strength (adhesion to low-profile copper) was low because the component (B) was not contained or the amount of the component (B) added was small relative to the amount of the component (A) added.

In Comparative Examples 5 and 7, the desmear treatment resistance was low because the component (A) was not contained or the amount of the component (A) added was small relative to the amount of the component (B) added.

### Method for Producing Prepreg

In Working Examples 13 to 16 and Comparative Examples 8 to 11, prepregs were produced using the resin compositions prepared in Working Examples 1 to 4 and Comparative Examples 4 to 7 by mixing 1,000 g of each resin composition with 1,000 g of cyclopentanone, impregnating a quartz glass cloth SQX2116AC (thickness: 90 μm, manufactured by Shin-Etsu Chemical Co., Ltd.) with the mixture, and heating the impregnated cloth at 120° C. for 5 minutes to volatilize cyclopentanone. The resin composition content (% by mass) and the prepreg thickness are shown in Table 3.

### Method for Producing Copper-Clad Laminate

Ten pieces of each prepreg obtained as above and nine pieces of copper foil with a thickness of 18 μm (trade name: TQ-M4-VSP, manufactured by Mitsui Mining & Smelting Co., Ltd.) were alternately stacked, and the copper foil was further stacked on the topmost and bottommost surfaces thereof, followed by pressing at 3 MPa and heating at 180° C. for 1 hour to produce a double-sided copper-clad laminate.

### Method for Producing Printed-Wiring Board

Dry resist films (NIT430E, manufactured by Nikko-Materials Co., Ltd.) with a thickness of 30 μm were laminated on both surfaces of the double-sided copper-clad laminate obtained as above by vacuum lamination at 80° C. for 60 seconds. A mask having a circuit pattern formed therein was then brought into contact with the laminate, followed by UV irradiation at an intensity of 500 mW from above and below for 10 seconds. Development was then performed by immersion in a 10% sodium hydrogen carbonate aqueous solution at 40° C. for 10 minutes. Etching was then performed by immersion in an etchant (H-1000A, manufactured by Sunhayato Corp.) at 40° C. for 10 minutes. Washing was then performed by immersion in a 10% sodium hydroxide aqueous solution at 40° C. for 20 minutes. Thus, a printed-wiring board having circuitry formed on both sides thereof were produced.

### Transmission Loss

A network analyzer (manufactured by Keysight Technologies, Product No. E5071C) was used to measure the transmission loss at 40 GHz. In the measurement, the conductor length was 400 mm, the thickness of the copper foil was 18 μm, the line width was 0.12 mm, the thickness of the insulating layer was 0.20 mm, and the characteristic impedance was adjusted to 50Ω. The results are shown in Table 3.

### Temperature Cycle Test

The produced printed-wiring boards were subjected to a thermal cycle test (TCT) in the range from −65° C. to 125° C. for 1,000 cycles, and the presence or absence of poor continuity was observed. The results are shown in Table 3.

TABLE 3

| | | | Working | Working | Working | Working | Comparative | Comparative | Comparative | Comparative |
|---|---|---|---|---|---|---|---|---|---|---|
| | | | Example 13 | Example 14 | Example 15 | Example 16 | Example 8 | Example 9 | Example 10 | Example 11 |
| | | | Working | Working | Working | Working | Comparative | Comparative | Comparative | Comparative |
| Resin composition | | | Example 1 | Example 2 | Example 3 | Example 4 | Example 4 | Example 5 | Example 6 | Example 7 |
| Evaluation | Resin | % by | 45 | 46 | 55 | 50 | 55 | 48 | 49 | 52 |
| results | composition | mass | | | | | | | | |
| | content | | | | | | | | | |
| | Prepreg | μm | 150 | 160 | 160 | 150 | 150 | 160 | 160 | 150 |
| | thickness | | | | | | | | | |
| | Transmission | dB/m | −16 | −16 | −20 | −20 | −20 | −45 | −20 | −50 |
| | loss | | | | | | | | | |
| | (40 GHz) | | | | | | | | | |
| | Poor | | None | None | None | None | Occurred | None | Occurred | None |
| | continuity | | | | | | | | | |

In Working Examples 13 to 16, the transmission loss was low, and no poor continuity was observed.

In Comparative Examples 8 and 10, poor continuity occurred after the temperature cycle test because the peeling strength of the resin to the copper foil (adhesion to low-profile copper) was low.

In Comparative Examples 9 and 11, the transmission loss was high because the interface between the resin and the copper foil was rough due to the poor desmear treatment resistance of the resin.

What is claimed is:

1. A resin composition comprising the following components (A) to (D):
(A) a first cyclic imide compound represented by: 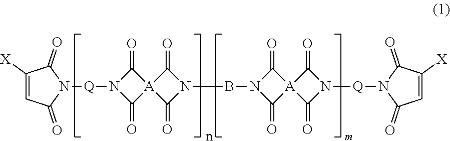
wherein A independently represents a tetravalent organic group having a cyclic structure, Q independently represents an alicyclic hydrocarbon group represented by: 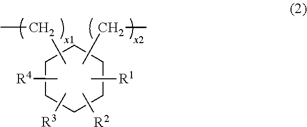
wherein R¹, R², R³, and R⁴ independently represent a hydrogen atom or an alkyl group having 1 to 5 carbon atoms, and x1 and x2 are each 0 to 4,
wherein B independently represents any one of divalent hydrocarbon groups represented by the following formulae: 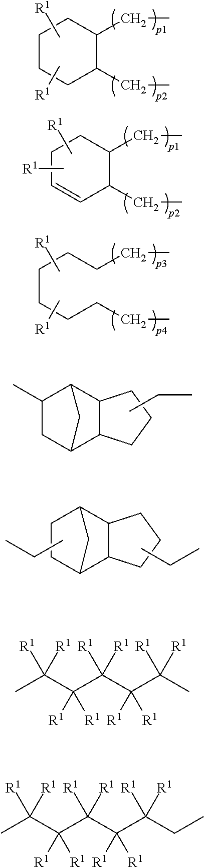
wherein bonds that are yet unbonded to substituent groups are to be bonded to nitrogen atoms forming cyclic imide structures in the formula (1), each R¹ independently represents a hydrogen atom or a linear or branched alkyl group having 1 to 20 carbon atoms, p¹ and p² are each a number of 5 or more and may be identical to or different from each other, and p³ and p⁴ are each a number of 0 or more and may be identical to or different from each other,
wherein X represents a hydrogen atom or a methyl group, and
wherein n is 1 to 200, m is 0 to 200, provided that when m is 1 or more, n:m=1:1 to 4:1, and repeating units identified by n and m may be present in any order;
(B) a second cyclic imide compound represented by: 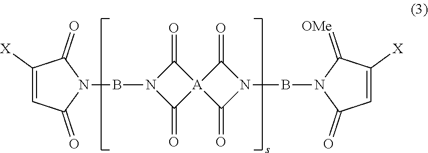
wherein A independently represents a tetravalent organic group having a cyclic structure,
wherein B independently represents any one of divalent hydrocarbon groups represented by the following formulae: 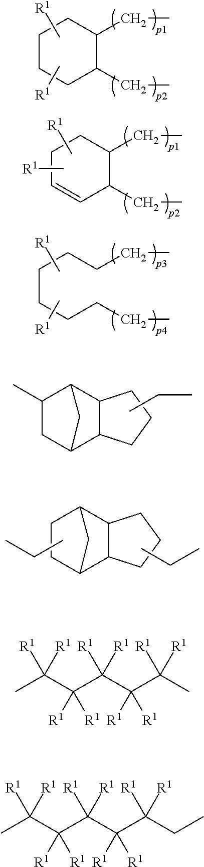
wherein bonds that are yet unbonded to substituent groups are to be bonded to nitrogen atoms forming cyclic imide structures in the formula (3), each R¹ independently represents a hydrogen atom or a linear or branched alkyl group having 1 to 20 carbon atoms, p¹ and p² are each a number of 5 or more and may be identical to or different from each other, and p³ and p⁴ are each a number of 0 or more and may be identical to or different from each other,
wherein X represents a hydrogen atom or a methyl group, and
wherein s is 0 to 200;
(C) an epoxy compound; and
(D) a curing catalyst,
wherein the first cyclic imide compound (A) is contained in an amount of 60 to 90 parts by mass and the second cyclic imide compound (B) is contained in an amount of 10 to 40 parts by mass per 100 parts by mass of a total of the first and second cyclic imide compounds (A) and (B).

2. The resin composition according to claim 1, wherein the organic group represented by A in the formula (1) is any one of tetravalent organic groups represented by the following structural formulae: 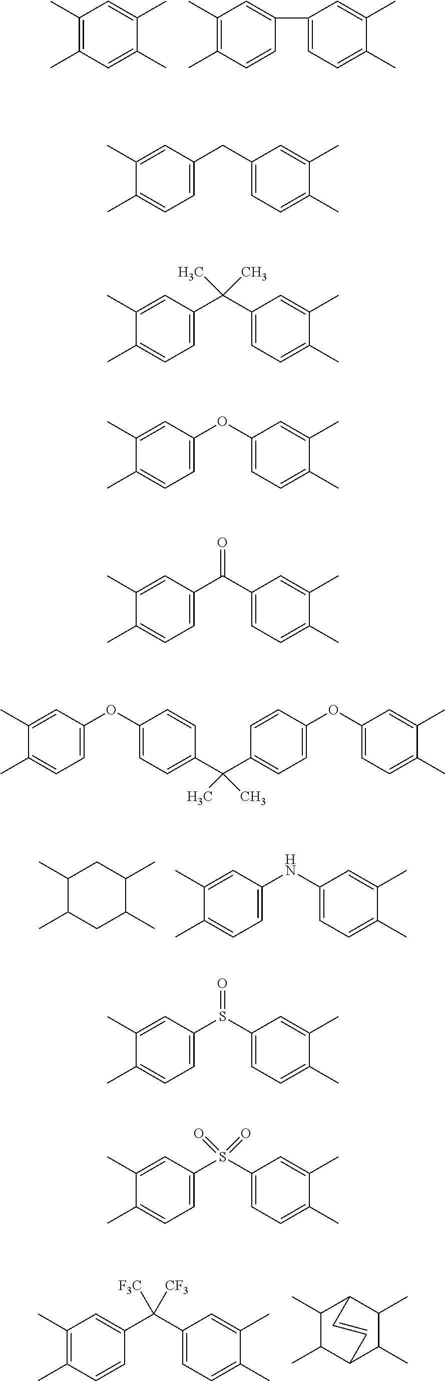 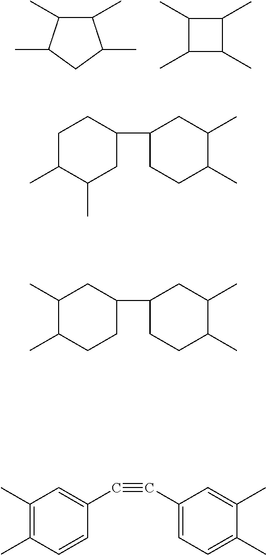
wherein bonds that are yet unbonded to substituent groups are to be bonded to carbonyl carbons forming the cyclic imide structures in the formula (1).

3. A prepreg comprising the resin composition according to claim 1.

4. A copper-clad laminate comprising the prepreg according to claim 3.

5. A printed-wiring board comprising the copper-clad laminate according to claim 4.
